(19) United States
(12) Patent Application Publication
(10) Pub. No.: US 2016/0218323 A1
(43) Pub. Date: Jul. 28, 2016

(54) ORGANIC LIGHT EMITTING DISPLAY DEVICE AND METHOD OF MANUFACTURING THE SAME

(71) Applicant: SAMSUNG DISPLAY CO., LTD., Yongin-si (KR)

(72) Inventor: Seokhoon Seo, Yongin-si (KR)

(21) Appl. No.: 14/827,254

(22) Filed: Aug. 14, 2015

(30) Foreign Application Priority Data
Jan. 22, 2015 (KR) 10-2015-0010553

(51) Int. Cl. H01L 51/52; H01L 51/56; H01L 27/32

(52) U.S. Cl. CPC H01L 51/5268; H01L 51/5256; H01L 51/5275; H01L 27/3244; H01L 51/56; H01L 2227/323

(57) ABSTRACT

An organic light emitting display device includes a substrate, an organic light emitting device on the substrate and including a first electrode, an intermediate layer on the first electrode and including an emission layer, and a second electrode on the intermediate layer, and a thin film encapsulation film on the organic light emitting device in an emission direction of the emission layer, wherein the thin film encapsulation film includes a scattering layer including scatterers having a three-dimensional structure and an organic layer on the scattering layer and including a first organic material.

### CROSS-REFERENCE TO RELATED APPLICATION

This application claims priority to and the benefit of Korean Patent Application No. 10-2015-0010553, filed on Jan. 22, 2015 in the Korean Intellectual Property Office, the disclosure of which is incorporated herein in its entirety by reference.

### BACKGROUND

1. Field

One or more exemplary embodiments of the present disclosure relate to an organic light emitting display device and a method of manufacturing the same.

2. Description of the Related Art

An organic light emitting display device is a self-emissive display device that does not require an additional light source. Thus, the organic light emitting display device may be driven at a relatively low voltage and may be manufactured to be lightweight and thin. Also, the organic light emitting display device has high quality characteristics, such as a wide viewing angle, a high contrast ratio, and a fast response speed, and is thusly regarded as a next-generation display device.

The organic light emitting display device may deteriorate due to external moisture and/or oxygen, and thus, the organic light emitting device is generally encapsulated in order to protect it from penetration of external moisture and oxygen.

Light may be emitted from the organic light emitting device to the outside through an encapsulation member disposed thereon. In this case, due to different light paths, a color shift may be caused at a side viewing angle (e.g., at an increased viewing angle) of the organic light emitting display device.

### SUMMARY

One or more exemplary embodiments of the present disclosure include an organic light emitting display device and a method of manufacturing the organic light emitting display device.

Additional aspects will be set forth, in part, in the description which follows and, in part, will be apparent from the description or may be learned by practice of the presented embodiments.

According to one or more exemplary embodiments of the present disclosure, an organic light emitting display device includes: a substrate; an organic light emitting device on the substrate and including a first electrode, an intermediate layer on the first electrode and including an emission layer, and a second electrode on the intermediate layer; and a thin film encapsulation film on the organic light emitting device in an emission direction of the emission layer, wherein the thin film encapsulation film includes: a scattering layer including scatterers having a three-dimensional spiral structure; and an organic layer on the scattering layer and including a first organic material.

The scatterers may have a cylindrical spiral structure that is rotated about an axis in a clockwise or counter-clockwise direction and has at least one pitch.

Each of the scatterers may have a first void.

At least a portion of the first void may be filled with the first organic material.

A second void may be formed between adjacent scatterers in the scattering layer, and at least a portion of the first and second voids may be filled with the first organic material.

A refractive index of the scatterers may be different from a refractive index of the first organic material.

The scatterers may include an inorganic material.

The thin film encapsulation film may further include an inorganic layer and/or an organic layer.

The thin film encapsulation film includes the organic layer, the thin film encapsulation film may further include a first inorganic layer interposed between the organic light emitting device and the scattering layer and a second inorganic layer on the organic layer.

According to one or more exemplary embodiments of the present disclosure, a method of manufacturing an organic light emitting display device, includes: forming an organic light emitting device on a substrate, the organic light emitting device including a first electrode, an intermediate layer on the first electrode and including an emission layer, and a second electrode on the intermediate layer; and forming a thin film encapsulation film on the organic light emitting device, wherein the forming of a thin film encapsulation film includes: forming a scattering layer including scatterers having a three-dimensional spiral structure; and forming an organic layer on the scattering layer, the organic layer including a first organic material.

The scatterers may have a cylindrical spiral structure that is rotated about an axis in a clockwise or counter-clockwise direction and has at least one pitch.

Each of the scatterers may have a first void.

In the forming of an organic layer, at least a portion of the first void may be filled with the first organic material.

A second void may be between adjacent scatterers in the scattering layer, and in the forming of an organic layer, at least a portion of the first void and the second void may be filled with the first organic material.

The forming of the scattering layer may include utilizing an oblique angle deposition method or a glancing angle deposition method.

A refractive index of the first organic material may be different from a refractive index of the scatterers.

The scatterers may include an inorganic material.

The method may further include forming a first inorganic layer between the organic light emitting device and the scattering layer.

The method may further include forming a second inorganic layer on the organic layer.

### BRIEF DESCRIPTION OF THE DRAWINGS

These and/or other aspects will become apparent and more readily appreciated from the following description of exemplary embodiments, taken in conjunction with the accompanying drawings in which:

FIG. 1 is a schematic cross-sectional view illustrating an organic light emitting display device according to an exemplary embodiment of the present disclosure;

FIG. 2 is a detailed cross-sectional view showing portions of a substrate and an organic light emitting device shown in FIG. 1;

FIG. 3A illustrates a portion of a scattering layer according to an exemplary embodiment of the present disclosure;

FIG. 3B is a scanning electron microscope (SEM) photographic image according to an exemplary embodiment of the present disclosure;

FIG. 4A is an expanded view of the portion IV of the organic light emitting display device shown in FIG. 1;

FIG. 4B is a SEM photographic image of the portion IV of FIG. 4A;

FIG. 5 is a schematic cross-sectional view of an organic light emitting display device according to a comparative example; and

FIGS. 6 through 10 are cross-sectional views illustrating a method of manufacturing an organic light emitting display device according to an exemplary embodiment of the present disclosure.

### DETAILED DESCRIPTION

Reference will now be made in detail to exemplary embodiments, examples of which are illustrated in the accompanying drawings, wherein like reference numerals refer to like elements throughout. In this regard, the presented exemplary embodiments may have different forms, and the present disclosure should not be construed as being limited to the descriptions set forth herein. Accordingly, exemplary embodiments are merely described below, by referring to the figures, to explain aspects of the present description. As used herein, the term “and/or” includes any and all combinations of one or more of the associated listed items. Expressions, such as “at least one of,” when preceding a list of elements, modify the entire list of elements and do not modify the individual elements of the list.

Because the inventive concept may have various modifications and several embodiments, exemplary embodiments are shown in the drawings and will be described in more detail. Aspect(s), feature(s), and method(s) of achieving the same will be described with reference to the exemplary embodiments described below in more detail together with the attached drawings. However, the exemplary embodiments and the present disclosure may have different forms and should not be construed as being limited to the descriptions set forth herein.

Exemplary embodiments of the inventive concept will be described below in more detail with reference to the accompanying drawings.

Singular expressions, unless defined otherwise in contexts, include plural expressions.

In the exemplary embodiments below, it will be further understood that the terms “include,” “comprise,” and/or “have” used herein specify the presence of stated features or components but do not preclude the presence or addition of one or more other features or components.

In the exemplary embodiments below, it will be understood when a portion, such as a layer, an area, or an element, is referred to as being “on” or “above” another portion, it can be directly on or above the other portion, or an intervening portion or portions may also be present.

Also, in the drawings, for convenience of description, sizes of elements may be exaggerated or contracted. Because sizes and thicknesses of components in the drawings may be arbitrarily illustrated for convenience of explanation, the following embodiments are not limited thereto.

When an exemplary embodiment is implementable in another manner, a set or predetermined process order may be different from a described one. For example, two processes that are consecutively described may be substantially concurrently or simultaneously performed or may be performed in an opposite order to the described order.

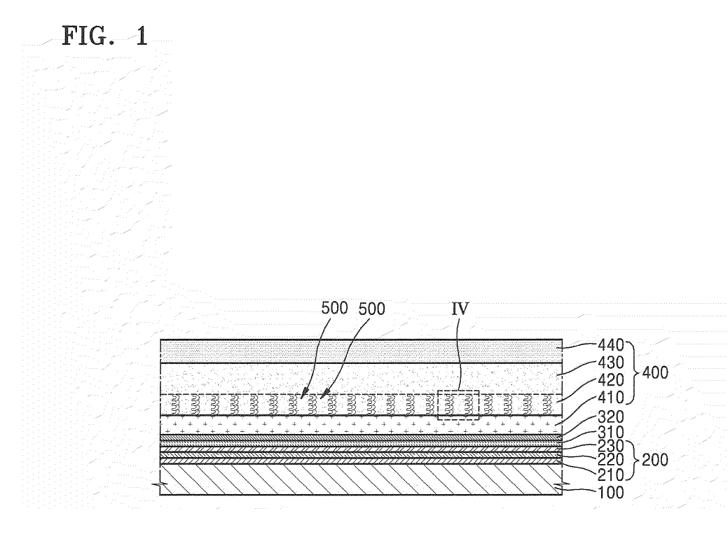

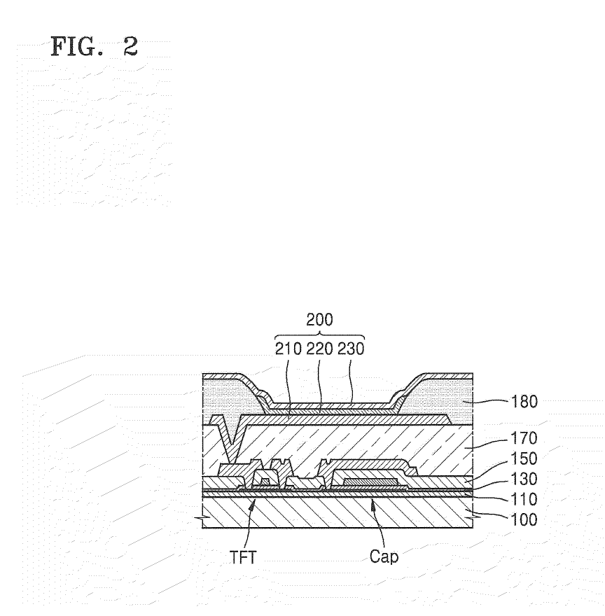

FIG. 1 is a schematic cross-sectional view illustrating an organic light emitting display device according to an exemplary embodiment of the present disclosure. FIG. 2 is a detailed cross-sectional view of portions of a substrate and an organic light emitting device (OLED) shown in FIG. 1.

Referring to FIGS. 1 and 2, the organic light emitting display device may include a substrate 100, an OLED 200 formed on the substrate 100, and a thin film encapsulation film 400 disposed on the OLED 200 along an emission direction of light emitted (e.g., in the direction along which light is emitted) from the OLED 200. As shown in FIG. 2, at least one thin film transistor TFT and at least one storage capacitor Cap may be disposed between the substrate 100 and the OLED 200.

The substrate 100 may be rigid or flexible. The substrate 100 may be formed of various materials, such as a glass material, a metal, and/or a plastic material, such as polyethylene terephthalate (PET), polyethylene naphthalate (PEN), and/or polyimide.

Layers (such as a buffer layer 110 preventing penetration of impurities into a semiconductor layer of the thin film transistor TFT, a gate insulating layer 130 insulating the semiconductor layer and a gate electrode of the thin film transistor TFT from each other, an interlayer insulating layer 150 insulating a source electrode and a drain electrode of the thin film transistor TFT from the gate electrode, and/or a planarization layer 170 covering the thin film transistor TFT and having a substantially planar upper surface) may be disposed on the substrate 100.

The OLED 200 may include a first electrode 210, an intermediate layer 220 formed on the first electrode 210, and a second electrode 230 formed on the intermediate layer 220. According to the present exemplary embodiment, the first electrode 210 may be an anode and the second electrode 230 may be a cathode. However, exemplary embodiments of the present disclosure are not limited thereto, and the first electrode 210 may be a cathode and the second electrode 230 may be an anode according to a driving method of the organic light emitting display device. Holes and electrons respectively emitted from the first electrode 210 and the second electrode 230 are injected into an emission layer included in the intermediate layer 220. Excitons formed by the combination of the injected holes and electrons fall from an excitation state to a ground state, thereby emitting light.

The first electrode 210 may be electrically connected to the source electrode or the drain electrode of the thin film transistor TFT. The first electrode 210 may be a reflective electrode. According to an exemplary embodiment, the first electrode 210 may include a reflection layer including, for example, Ag, Mg, Al, Pt, Pd, Au, Ni, Nd, Ir, Cr, or a compound or alloy of these. According to another exemplary embodiment, the first electrode 210 may include a reflection layer including, for example, Ag, Mg, Al, Pt, Pd, Au, Ni, Nd, Ir, Cr, or a compound or alloy of these and a layer formed of ITO, IZO, ZnO, and/or In₂O₃ on the reflection layer.

A pixel defining layer 180 exposes an upper surface of the first electrode 210 through an opening, and the intermediate layer 220 may be disposed on an exposed portion of the upper surface of the first electrode 210.

The emission layer may include a low molecular weight organic material or/and a high molecular weight organic material capable of emitting light corresponding to a red, green, blue, or white color. The intermediate layer 220 may further include, in addition to the emission layer, a hole injection layer (HIL), a hole transport layer (HTL), an electron transport layer (ETL), and/or an electron injection layer (EIL).

The second electrode 230 may be a semi-transparent electrode or a transparent electrode. The second electrode 230 may include a layer formed of Li, Ca, LiF/Ca, LiF/Al, Al, Mg, or a compound or alloy thereof and a layer formed of a semi-transparent material or a transparent material, such as ITO, IZO, ZnO, and/or In₂O₃ on the above-described layer formed of Li, Ca, LiF/Ca, LiF/Al, Al, Mg, or a compound or alloy thereof.

The thin film encapsulation film 400 may be disposed on the OLED 200, and a capping layer 310 and/or a protection layer 320 may be further formed between the OLED 200 and the thin film encapsulation film 400.

The capping layer 310 may be formed on the OLED 200 to protect the OLED 200. The capping layer 310 may include 8-quinolinolato lithium, N,N-diphenyl-N,N-bis(9-phenyl-9H-carbazol-3-yl)biphenyl-4,4′-diamine, N(diphenyl-4-yl)9,9-dimethyl-N-(4(9-phenyl-9H-carbazol-3-yl)phenyl)-9H-fluorene-2-amine, and/or 2-(4-(9,10-di(naphthalene-2-yl)anthracene-2-yl)phenyl)-1-phenyl-1H-benzo-[D]imidazole, and/or the like but is not limited thereto.

The protection layer 320 is disposed on the capping layer 310 to protect the capping layer 310 and the OLED 200 from plasma that may be generated when forming the thin film encapsulation film 400. The protection layer 320 may include LiF but is not limited thereto.

The thin film encapsulation film 400 may include a first inorganic layer 410, a scattering layer 420, an organic layer 430 disposed on the scattering layer 420, and a second inorganic layer 440.

The first inorganic layer 410 may prevent (or protect from) penetration of foreign substances, such as moisture (H₂O) and/or oxygen (O₂), and may include a first inorganic material. For example, the first inorganic material may include AlOₓ, TiO₂, ZrO, SiO₂, AlON, SiON, ZnO, and/or Ta₂O₅ but is not limited thereto.

The scattering layer 420 includes scatterers 500 having three-dimensional spiral structures. For example, the scatterers 500 may have a cylindrical spiral structure having a clockwise or counter-clockwise twist or rotation with respect to an axis (e.g., a vertical axis) so as to have at least one pitch (e.g., so as to complete at least one full twist or revolution). The scatterers 500 may be an inorganic material. The scattering layer 420 is a layer formed of a plurality of scatterers 500 having three-dimensional spiral structures formed on the first inorganic layer 410 and may include a void.

The organic layer 430 is disposed directly on the scattering layer 420. The organic layer 430 may include a polymer-based first organic material. Examples of the polymer-based materials may include an acrylic resin, an epoxy resin, polyimide, and polyethylene but are not limited thereto. The organic layer 430 is formed to be thicker than the scattering layer 420 so as to cover the scattering layer 420. A portion of the organic layer 430, for example, a lower portion of the organic layer 430, may be filled in a void formed in the scattering layer 420 (e.g., may be filled in a void between the scatterers 500).

The second inorganic layer 440 may be disposed on the organic layer 430. The second inorganic layer 440 may prevent penetration of foreign substances, such as moisture (H₂O) and/or oxygen (O₂), and may include a second inorganic material. For example, the second inorganic material may include an inorganic material, such as AlOx, TiO₂, ZrO, SiO₂, AlON, SiON, ZnO, and/or Ta₂O₅ but is not limited thereto.

While the first inorganic layer 410 is formed under the scattering layer 420 and the second inorganic layer 440 is formed on the organic layer 430 in the present exemplary embodiment, exemplary embodiments of the present disclosure are not limited thereto. According to another exemplary embodiment, the organic layer 430 or an organic-inorganic complex layer may be formed under the scattering layer 420 and/or another organic layer 430 or an organic-inorganic complex layer may be formed on the organic layer 430.

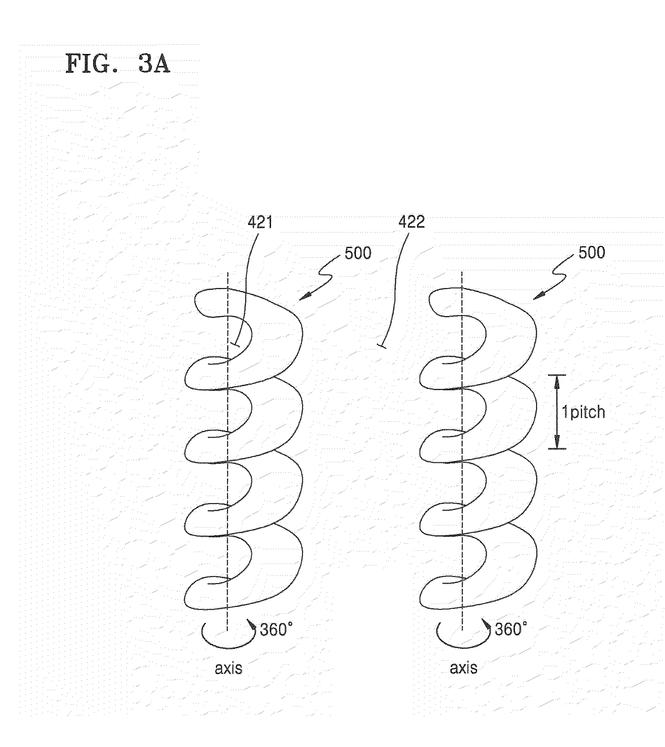

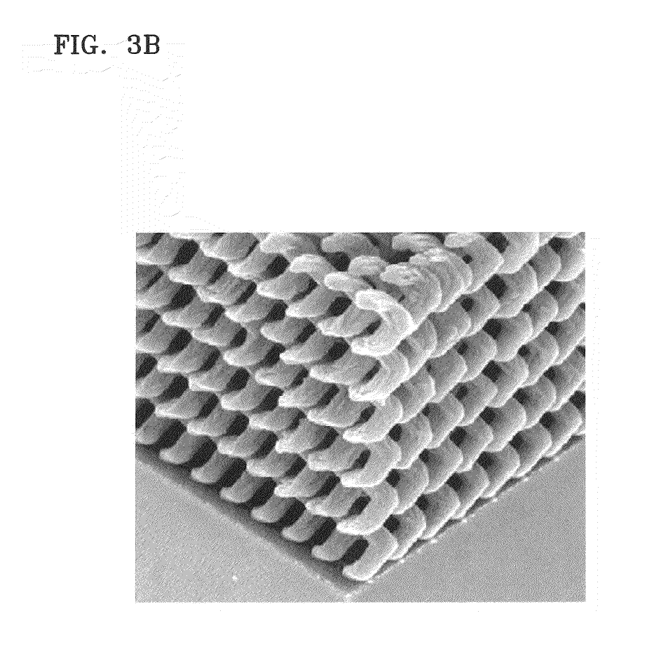

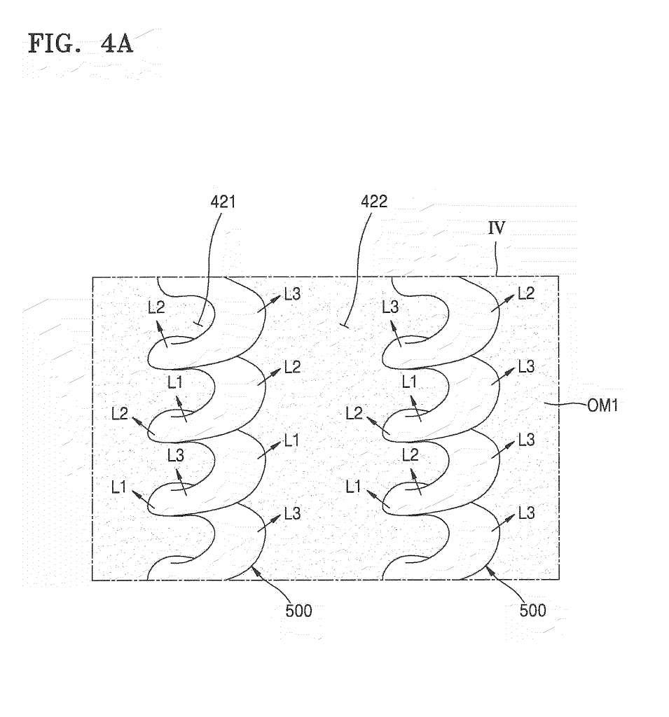

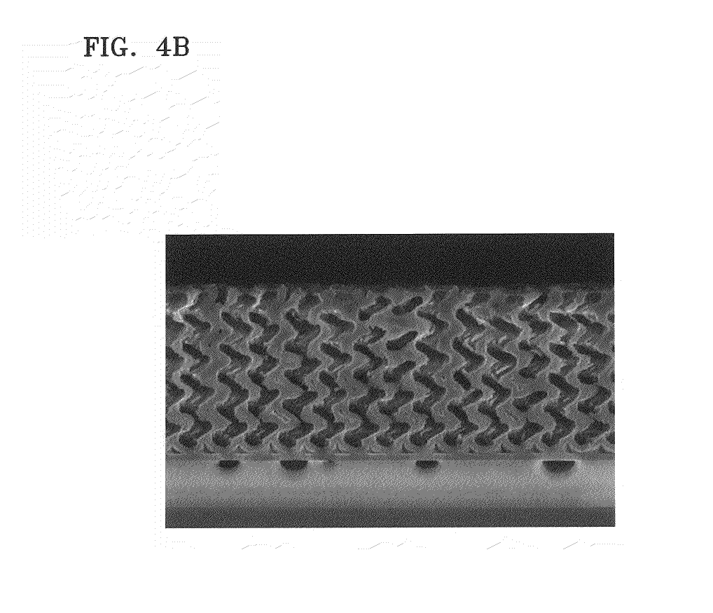

Hereinafter, the scattering layer 420 and a stacked structure including the scattering layer 420 and the organic layer 430 according to an exemplary embodiment of the present disclosure will be described in more detail with reference to FIGS. 3A through 4B.

FIG. 3A illustrates a portion of the scattering layer 420 according to an exemplary embodiment of the present disclosure. FIG. 3B is a scanning electron microscope (SEM) photographic image showing a portion of the scattering layer 420 according to an exemplary embodiment of the present disclosure. FIG. 4A is an expanded view of the portion IV of the organic light emitting display device shown in FIG. 1. FIG. 4B is a SEM side photographic image of the portion IV of FIG. 4A.

Referring to FIGS. 3A and 3B, the scattering layer 420 includes the scatterers 500 having three-dimensional spiral structures. The scatterers 500 each have a three-dimensional spiral structure that is twisted or rotated about an axis at least once in a clockwise or counter-clockwise direction. For example, the scatterers 500 may have a cylindrical spiral structure (e.g., a helix structure) that is twisted or rotated about an axis in a clockwise or counter-clockwise direction and forms at least one pitch.

While the scatterers 500 having a cylindrical spiral structure are described with reference to FIGS. 3A and 3B, exemplary embodiments of the present disclosure are not limited thereto. The scatterers 500 may have any three-dimensional spiral structure having at least one pitch about an axis, and the shape (e.g., the entire or overall shape) of the scatterers 500 may be modified in various suitable manners, for example, to be a spherical spiral structure.

The scatterers 500 may include an inorganic material, such as SiOₓ, SiNₓ, ITO, AlOₓ, ZrOₓ, Ta₂O₅, MgF₂, InN, and/or CrN. For example, the scatterers 500 may be formed by growing an inorganic material about an axis in a clockwise or counter-clockwise direction. The scatterers 500 have the form of spirals spaced from (e.g., spaced apart by predetermined distances from) the axis, and thus, a hollow space, that is, a first void 421, may be formed inside each of the scatterers 500. The scattering layer 420 is a layer formed by forming the scatterers 500 having a three-dimensional spiral structure such that a hollow space, that is, a second void 422, may be formed between adjacent scatterers 500.

Referring to FIGS. 4A and 4B, a portion of the organic layer 430 formed on the scattering layer 420 may at least partially fill the first and second voids 421 and 422 formed in the scattering layer 420. For example, a portion of the first organic material OM1 forming the organic layer 430 may also be filled in the first and second voids 421 and 422 formed in the scattering layer 420.

The organic layer 430 may be formed by depositing a liquid or gasified monomer and irradiating light, such as ultraviolet light, to the monomer to harden the deposition material. The liquid or gasified monomer may penetrate into the first void 421 and the second void 422 to fill the first void 421 and the second void 422 and may be polymerized by heat or the light. Accordingly, a portion of the organic layer 430 may at least partially fill the first void 421 and the second void 422. For example, the first organic material OM1 of the organic layer 430 may at least partially fill the first void 421 and the second void 422. A refractive index of the first organic material OM1 may be different from that of an inorganic material of the scatterers 500.

As described above with reference to FIGS. 3A and 3B, the scatterers 500 have three-dimensional spiral structures that are rotated by 360° or more and form at least one pitch about an axis. Thus, because refractive indices of the scatterers 500 and the first organic material OM1 are different from each other, light L1, L2, and L3 emitted from the emission layer may be scattered in multiple directions (e.g., all directions) regardless of a wavelength thereof.

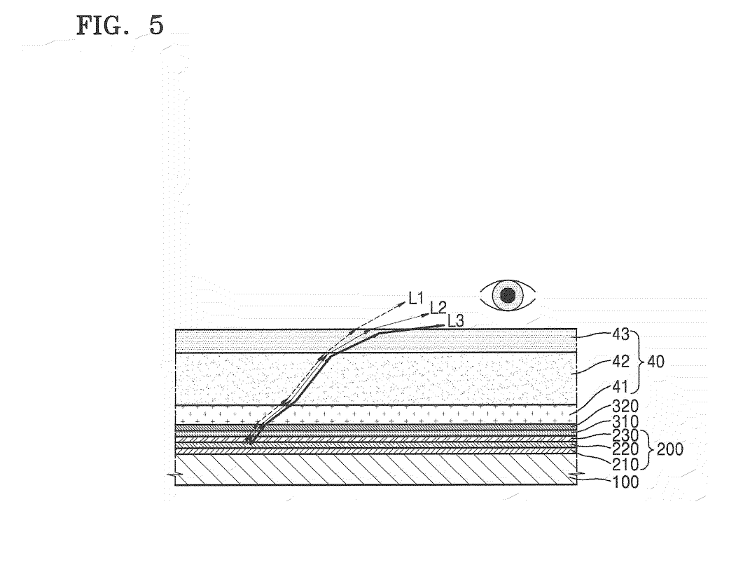

FIG. 5 is a schematic cross-sectional view of an organic light emitting display device according to a comparative example.

Referring to FIG. 5, in the organic light emitting display device according to the comparative example, a thin film encapsulation film 40 does not include the scattering layer 420 but includes a first inorganic layer 41, an organic layer 42, and a second inorganic layer 43. Light emitted from an emission layer of the organic light emitting display device according to the comparative example is viewed by a user after passing through layers along a light path of the emitted light, that is, through a capping layer 310, a protection layer 320, and the thin film encapsulation film 40. In this comparative example, the light path changes due to a difference in refractive indices of the respective layers. Also, the light path changes according to a wavelength of the emitted light. For example, red light L1, green light L2, and blue light L3 have different wavelengths, and thus, the emitted light refracts differently in each of the respective layers, and thus, a color shift is caused at a side viewing angle (e.g., at an increased viewing angle).

However, according to embodiments of the present disclosure, because the scatterers 500 have three-dimensional spiral structures and the scatterers 500 and the first organic material OM1 have different refractive indices, light emitted from the emission layer may be scattered in multiple directions (e.g., all directions) regardless of the wavelength of the emitted light (see FIGS. 4A and 4B). Accordingly, color shift caused at the side viewing angle may be reduced or prevented.

The first and second voids 421 and 422 of the scattering layer 420 are filled with the first organic material OM1. Thus, light L that passes through the first and second voids 421 and 422 may pass through the first organic material OM1 without being scattered and is emitted to the outside without being changed (e.g., shifted or refracted), and thus, front viewability may also be provided (e.g., front viewability may not be affected).

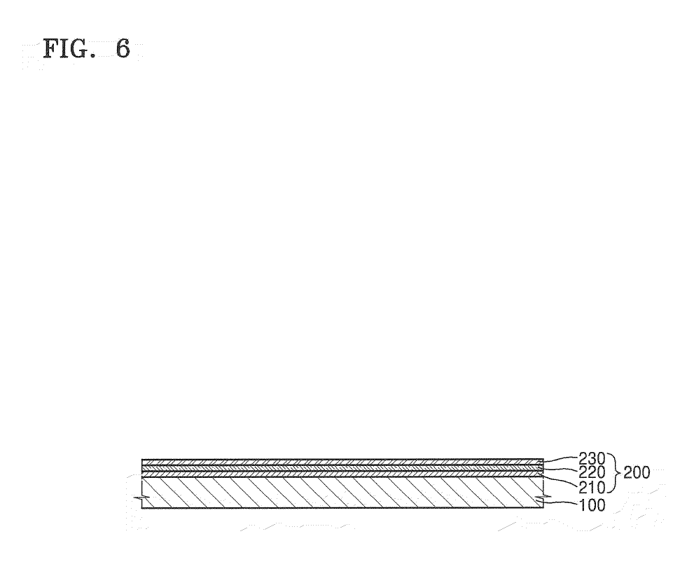

FIGS. 6 through 10 are cross-sectional views illustrating a method of manufacturing an organic light emitting display device according to an exemplary embodiment of the present disclosure.

Referring to FIG. 6, an OLED 200 is formed on a substrate 100. The OLED 200 may include a first electrode 210, an intermediate layer 220 including an emission layer, and a second electrode 230.

Before forming the OLED 200, various layers may be formed on the substrate 100. As described with reference to FIG. 2, a thin film transistor TFT and a storage capacitor Cap may be formed on the substrate 100. Insulating layers, such as a buffer layer 110 preventing penetration of impurities into a semiconductor layer of the thin film transistor TFT, a gate insulating layer 130 insulating the semiconductor layer and a gate electrode of the thin film transistor TFT from each other, an interlayer insulating layer 150 insulating a source electrode and a drain electrode of the thin film transistor TFT from the gate electrode, and/or a planarization layer 170 covering the thin film transistor TFT and having a substantially planar upper surface may be formed on the substrate 100.

The first electrode 210 may include a reflection layer including, for example, Ag, Mg, Al, Pt, Pd, Au, Ni, Nd, Ir, Cr, or a compound or alloy of these. According to another exemplary embodiment, the first electrode 210 may include a reflection layer including one or more of the above elements or compounds and a layer formed of ITO, IZO, ZnO, and/or In₂O₃ on the reflection layer.

A pixel defining layer 180 exposes an upper surface of the first electrode 210 through an opening. The pixel defining layer 180 may increase a distance between an end portion of the first electrode 210 and the second electrode 230 so as to reduce or prevent generation of an arc or the like at the end portion of the first electrode 210.

The intermediate layer 220 may include an emission layer. The emission layer may include a low molecular weight organic material and/or a high molecular weight organic material capable of emitting light corresponding to a red, green, blue, or white color. The intermediate layer 220 may further include, in addition to the emission layer, a hole injection layer (HIL), a hole transport layer (HTL), an electron transport layer (ETL), and/or an electron injection layer (EIL).

The second electrode 230 may be formed of a semi-transparent electrode or a transparent electrode. The second electrode 230 may be formed by forming a layer including, for example, L1, Ca, LiF/Ca, LiF/Al, Al, Mg, or a compound or alloy of these and a layer formed of a semi-transparent material or a transparent material, such as ITO, IZO, ZnO, and/or In₂O₃ on the above-described layer so as to be formed as a semi-transparent electrode or a transparent electrode.

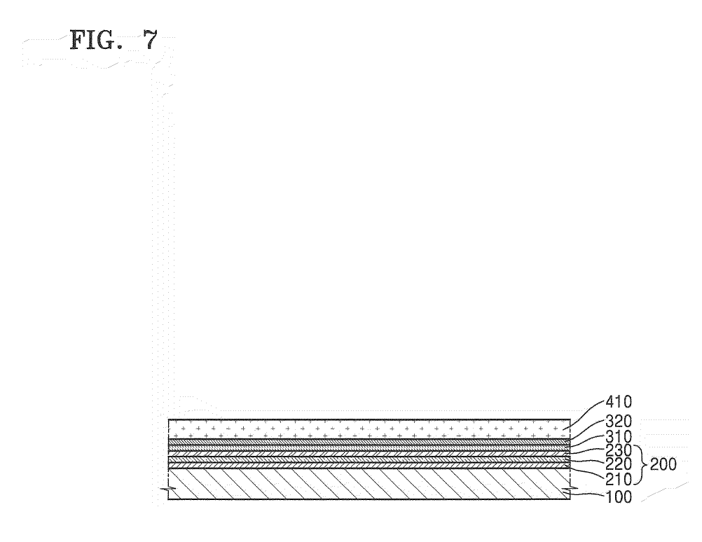

Referring to FIG. 7, a capping layer 310 and a protection layer 320 may be formed on the OLED 200. The capping layer 310 may include 8-quinolinolato lithium, N,N-diphenyl-N,N-bis(9-phenyl-9H-carbazol-3-yl)biphenyl-4,4′-diamine, N(diphenyl-4-yl)9,9-dimethyl-N-(4(9-phenyl-9H-carbazol-3-yl)phenyl)-9H-fluorene-2-amine, and/or 2-(4-(9,10-di(naphthalene-2-yl)anthracene-2-yl)phenyl)-1-phenyl-1H-benzo-[D]imidazole and/or the like but is not limited thereto.

The protection layer 320 may be deposited using a method, such as an evaporation method, and may include LiF but is not limited thereto.

A first inorganic layer 410 may be formed on the protection layer 320. The first inorganic layer 410 may prevent penetration of foreign substances, such as moisture (H₂O) and/or oxygen (O₂), and may be formed using a CVD method. The first inorganic layer 410 may include AlOₓ, TiO₂, ZrO, SiO₂, AlON, SiON, ZnO, and/or Ta₂O₅ but is not limited thereto.

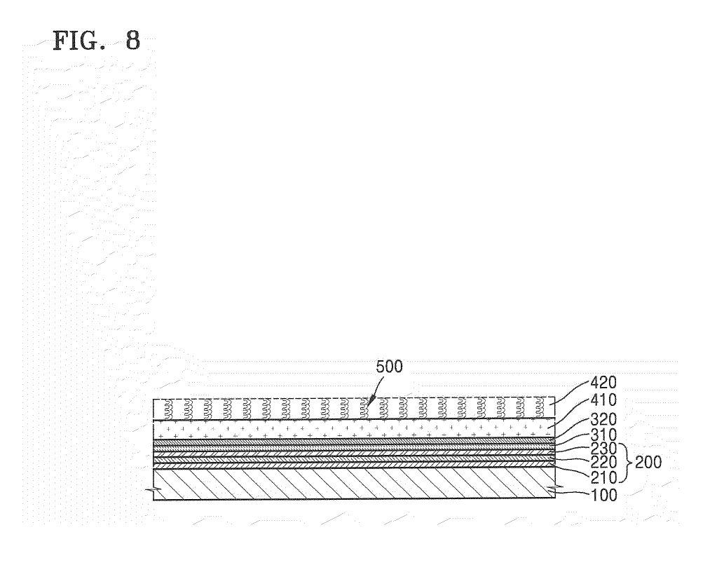

Referring to FIG. 8, a scattering layer 420 is formed on the first inorganic layer 410. The scattering layer 420 may include scatterers 500 having three-dimensional spiral structures, and the scatterers 500 may be formed of an inorganic material, such as SiOₓ, SiNₓ, ITO, AlOₓ, ZrOₓ, Ta₂O₅, MgF₂, InN, and/or CrN but are not limited thereto.

The scatterers 500 may have three-dimensional spiral structures having at least one pitch with respect to an axis and formed by using an oblique angle deposition method or a glancing angle deposition method. For example, the scatterers 500 may be formed by growing an inorganic material with respect to an axis in a clockwise or counter-clockwise direction. As described with reference to FIG. 3A, the scatterers 500 may have a first void 421 formed thereinside and a second void 422 may be formed between adjacent scatterers 500.

A size, a density, a pitch distance, and/or the number of pitches (e.g., the number of rotations) of the scatterers 500 or an inclination of an axis of the scatterers 500 or the like may be adjusted by controlling a speed or a direction of an injection source, a direction of deposition, or the like in the oblique angle deposition method or the glancing angle deposition method.

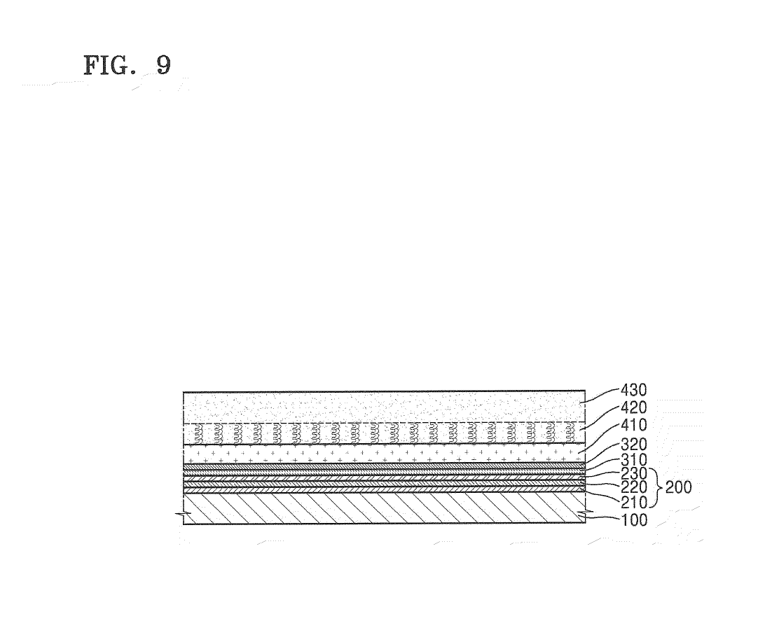

Referring to FIG. 9, an organic layer 430 is formed on the scattering layer 420. After depositing a liquid or gasified monomer on the scattering layer 420 having the first void 421 and the second void 422, ultraviolet light may be irradiated to the monomer to form the organic layer 430. The monomer may be polymerized to a polymer by ultraviolet light irradiation.

The organic layer 430 may include a polymer-based organic material, such as an acrylic resin, an epoxy resin, polyimide, and/or polyethylene. A refractive index of the organic material of the organic layer 430 is different from that of the scatterers 500.

According to exemplary embodiments of the present disclosure, because the scatterers 500 have three-dimensional spiral structures and the scatterers 500 and the organic material of the organic layer 430 have different refractive indices, light emitted from the emission layer is scattered in multiple directions (e.g., all directions) regardless of wavelength and, thus, color shift caused at a side viewing angle may be reduced or prevented as described above with reference to FIGS. 3A through 4B.

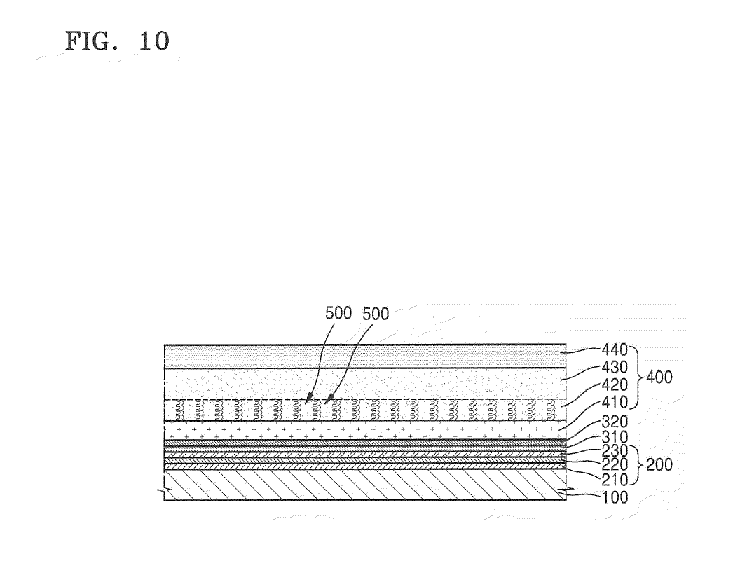

Referring to FIG. 10, a second inorganic layer 440 may be formed on the organic layer 430. The second inorganic layer 440 may prevent penetration of foreign substances, such as moisture (H₂O) and/or oxygen (O₂), and may be formed using a CVD method. The second inorganic layer 440 may include an inorganic material, such as AlOₓ, TiO₂, ZrO, SiO₂, AlON, SiON, ZnO, and/or Ta₂O₅ but is not limited thereto.

While the first inorganic layer 410 is formed on the protection layer 320 according to the present exemplary embodiment, exemplary embodiments of the present disclosure are not limited thereto. According to another exemplary embodiment, the organic layer 430 or an organic-inorganic complex layer may be formed on the protection layer 320.

While the second inorganic layer 440 is formed on the organic layer 430 according to the present exemplary embodiment, exemplary embodiments of the present disclosure are not limited thereto. According to another exemplary embodiment, another organic layer 430 or an organic-inorganic complex layer may be formed on the organic layer 430.

As described above, according to the organic light emitting display device of one or more of the above-described exemplary embodiments, color shift generated at a side viewing angle or white angular dependency (WAD) may be reduced.

It should be understood that the exemplary embodiments described herein should be considered in a descriptive sense only and not for purposes of limitation. Descriptions of features or aspects within each exemplary embodiment should typically be considered as available for other similar features or aspects in other exemplary embodiments.

While one or more exemplary embodiments have been described with reference to the figures, it will be understood by those of ordinary skill in the art that various changes in form and details may be made therein without departing from the spirit and scope as defined by the following claims and their equivalents.

The terms “first”, “second”, etc. are used herein to distinguish one component from another and do not limit these components. It will be understood that when an element or layer is referred to as being “on”, “connected to”, or “coupled to” another element or layer, it may be directly on, connected, or coupled to the other element or layer or one or more intervening elements or layers may also be present. When an element is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements. For example, it will be understood that when a portion, such as a layer, an area, or an element, is referred to as being electrically connected, it can be directly electrically connected or an intervening portion or portions may also be present. Also, the term “exemplary” is intended to refer to an example or illustration. Further, the use of “may” when describing embodiments of the present invention relates to “one or more embodiments of the present invention”.

What is claimed is:

1. An organic light emitting display device comprising:
a substrate;
an organic light emitting device on the substrate and comprising a first electrode, an intermediate layer on the first electrode and comprising an emission layer, and a second electrode on the intermediate layer; and
a thin film encapsulation film on the organic light emitting device in an emission direction of the emission layer,
wherein the thin film encapsulation film comprises:
a scattering layer comprising scatterers having a three-dimensional spiral structure; and
an organic layer on the scattering layer and comprising a first organic material.

2. The organic light emitting display device of claim 1, wherein the scatterers have a cylindrical spiral structure that is rotated about an axis in a clockwise or counter-clockwise direction and has at least one pitch.

3. The organic light emitting display device of claim 1, wherein each of the scatterers has a first void.

4. The organic light emitting display device of claim 3, wherein at least a portion of the first void is filled with the first organic material.

5. The organic light emitting display device of claim 3, wherein a second void is between adjacent scatterers in the scattering layer, and
at least a portion of the first and second voids are filled with the first organic material.

6. The organic light emitting display device of claim 1, wherein a refractive index of the scatterers is different from a refractive index of the first organic material.

7. The organic light emitting display device of claim 1, wherein the scatterers comprise an inorganic material.

8. The organic light emitting display device of claim 1, wherein the thin film encapsulation film further comprises an inorganic layer and/or an organic layer.

9. The organic light emitting display device of claim 8, wherein the thin film encapsulation film comprises the organic layer, and
the thin film encapsulation film further comprises a first inorganic layer interposed between the organic light emitting device and the scattering layer and a second inorganic layer on the organic layer.

10. A method of manufacturing an organic light emitting display device, the method comprising:
forming an organic light emitting device on a substrate, the organic light emitting device comprising a first electrode, an intermediate layer on the first electrode and comprising an emission layer, and a second electrode on the intermediate layer; and
forming a thin film encapsulation film on the organic light emitting device,
wherein the forming of a thin film encapsulation film comprises:
forming a scattering layer comprising scatterers having a three-dimensional spiral structure; and
forming an organic layer on the scattering layer, the organic layer comprising a first organic material.

11. The method of claim 10, wherein the scatterers have a cylindrical spiral structure that is rotated about an axis in a clockwise or counter-clockwise direction and has at least one pitch.

12. The method of claim 10, wherein each of the scatterers has a first void.

13. The method of claim 12, wherein in the forming of an organic layer, at least a portion of the first void is filled with the first organic material.

14. The method of claim 12, wherein a second void is between adjacent scatterers in the scattering layer, and
in the forming of an organic layer, at least a portion of the first void and the second void is filled with the first organic material.

15. The method of claim 10, wherein the forming of the scattering layer comprises utilizing an oblique angle deposition method or a glancing angle deposition method.

16. The method of claim 10, wherein a refractive index of the first organic material is different from a refractive index of the scatterers.

17. The method of claim 10, wherein the scatterers comprise an inorganic material.

18. The method of claim 10, further comprising forming a first inorganic layer between the organic light emitting device and the scattering layer.

19. The method of claim 10, further comprising forming a second inorganic layer on the organic layer.
